(19) United States
(12) Patent Application Publication
(10) Pub. No.: US 2021/0188056 A1
(43) Pub. Date: Jun. 24, 2021

(54) Window Sun Blind Arrangement, Control Circuit for a Window Sun Blind Arrangement and Vehicle With a Window Sun Blind Arrangement

(71) Applicant: Dometic Sweden AB, Solna (SE)

(72) Inventor: Herr Werner Dillhage, Dülmen (DE)

(21) Appl. No.: 17/127,448

(22) Filed: Dec. 18, 2020

(30) Foreign Application Priority Data
Dec. 20, 2019 (DE) 102019220488.0

(51) Int. Cl. B60J 1/20; H03K 17/687

(52) U.S. Cl. CPC B60J 1/2016; B60J 1/2019; H02P 29/00; H03K 17/6871; B60J 1/2052

(57) ABSTRACT

The present invention refers to a window sun blind arrangement having a control circuit, which comprises a second switching unit having a MOSFET-switch M1. The second switching unit comprises a control unit CU configured to operate the MOSFET-switch M1. The MOSFET-switch M1 has an activated operation state, in which electrical power can be supplied from an electric power supply to a second power port of a motor unit via a second power supply path II, and a non-activated operation state, in which electrical power cannot be supplied from the electric power supply to the motor unit via the second power supply path II. The control unit is configured to operate the MOSFET-switch M1 in the activated operation state, when a current flowing through the MOSFET-switch M1 and the motor unit does not exceed a predetermined threshold value, and to operate the MOSFET-switch M1 in the non-activated operation state, when the current flowing through the MOSFET-switch M1 and the motor unit exceeds the predetermined threshold value. Moreover, the present invention refers to an appropriate control circuit, to a vehicle with such a window sun blind arrangement or control circuit and to various methods for operating such window sun blind arrangements.

### CLAIM TO PRIORITY

This non-provisional patent application claims priority to and benefit of, under 35 U.S.C. § 119(a), German Patent Application Serial Number DE 102019220488.0, filed Dec. 20, 2019, all of which is incorporated by reference herein.

### BACKGROUND

The present embodiments refer to a window sun blind arrangement, a control circuit for such a window sun blind arrangement and a vehicle having such a window sun blind arrangement and/or control circuit.

### SUMMARY

Known window sun blind arrangements for vehicles comprise, for example, a base member, a dark-out-cloth fabric roller, a dark-out-cloth fabric, a drop bar, guiding means, an electrical motor unit and a control circuit. The base member is configured to be attached to a supporting surface, in particular a supporting surface of the vehicle. The dark-out-cloth fabric roller is attached in a rotatable manner to the base member. The dark-out-cloth fabric has a first and a second longitudinal end portion. The first longitudinal end portion of the dark-out-cloth fabric is coupled to the dark-out-cloth fabric roller so that the dark-out-cloth fabric can be rolled up onto or rolled off from the dark-out-cloth fabric roller by rotating the dark-out-cloth fabric roller with respect to the base member. The second longitudinal end portion of the dark-out-cloth fabric is coupled to the drop bar. A guiding arm is coupled to the base member and the drop bar. The guiding arm is configured to guide the drop bar during movement with respect to the base member along a predetermined path between an upper end position and a lower end position. In the upper end position the dark-out-cloth fabric is rolled up or retracted onto the dark-out-cloth fabric roller. In the lower end position the dark-out-cloth fabric is rolled off or extended from the dark-out-cloth fabric roller. The motor unit comprises two power ports and is configured to control the rotational movement of the dark-out-cloth fabric roller with respect to the base member based on a voltage level applied via the two power ports to the motor unit. The control circuit is coupled via an operating unit to an electric power supply and to the motor unit. The control circuit is configured to operate the motor unit with electrical power from the electric power supply based on an operation state of the operating unit.

Although, for such window sun blind arrangements various specific control circuits are known, there is still some room for further improvement thereof. It is an aim for such control circuits to react quickly on users demands and commands, i.e. in particular to start or stop the motor unit in a rapid and reliable way at distinct positions to avoid an undesired rolling on of the motor unit or even damages to the motor unit.

Accordingly, it is an object of the present embodiments to provide an improved configuration for such window sun blind arrangements. At the same time, an object of the present embodiments is to provide an improved control circuit for such a window sun blind arrangement and a vehicle benefiting from the therewith achieved technical effects. Finally, another object of the present embodiments is to provide advantageous methods for operating such window sun blind arrangements.

The afore mentioned problems and objects are solved by the window sun blind arrangement, the control circuit for such a window sun blind arrangement and the vehicle having such a window sun blind arrangement and/or control circuit according to the accompanying independent claims. Modifications of the therein claimed subject matters are given in the dependent claims.

According to a first aspect of the present embodiments, the control circuit comprises a second switching unit having a MOSFET-switch (metal-oxide semiconductor field-effect transistor). The second switching unit comprises a control unit configured to operate the MOSFET-switch. The MOSFET-switch has an activated operation state, in which electrical power can be supplied from the electric power supply to the second power port of the motor unit via a second power supply path. The MOSFET-switch has further a non-activated operation state, in which electrical power cannot be supplied from the electric power supply to the motor unit via the second power supply path. The control unit is configured to operate the MOSFET-switch in the activated operation state, when the current flowing through the MOSFET-switch and the motor unit does not exceed a predetermined threshold value. The control unit is configured to operate the MOSFET-switch in the activated operation state, when an electric current flowing through the MOSFET-switch and the motor unit exceeds the predetermined threshold value.

With such a configuration, for the off-rolling or the up-rolling process of the dark-out-cloth fabric, the motor unit is stopped as soon as a specific mechanical resistance is applied to the motor unit. Such a mechanical resistance, for example, occurs when the drop bar runs against and contacts the base member or when the rotational movement of the dark-out-cloth fabric is hindered by any other reason. Thus, damages to or malfunctions of the motor unit caused by such mechanical resistances are prevented in an efficient and reliable way.

The second power supply path leading from the electric power supply to the motor unit is configured to provide the motor unit with electrical power for the up-rolling process of the dark-out-cloth fabric onto the dark-out-cloth fabric roller. Thus, the above advantages are achieved for the up-rolling process, for example in the case the drop bar runs against the base member, thus, preventing damages to the motor unit in such a situation.

Further, the second switching unit is configured to stop the up-rolling process of the dark-out-cloth fabric onto the dark-out-cloth fabric roller as soon as the drop bar and, thus, the motor unit runs against a mechanical resistance. This configuration results in an effective and reliable prevention of damages to the motor unit when the drop bar reaches its upper end position.

The motor unit comprises a worm gear motor. Such a motor unit is space saving and reliable.

The threshold value for the electric current flowing through the MOSFET-switch and the motor unit voltage across the motor unit is selected in such a manner that the MOSFET-switch is activated before the motor unit gets stuck or becomes damaged from a mechanical resistance. Therewith, any damages to the motor unit are prevented in an efficient and reliable manner.

The control unit comprises a voltage regulator. The voltage regulator is coupled to a first power supply path leading from the electric power supply to the first power port of the motor unit via a regulator diode. Hereby, the voltage regulator allows to determine the voltage level applied to the two power ports. Moreover, the regulator diode prevents undesired electrical back couplings from the control unit to the first power supply path.

Further, the voltage regulator is coupled to a gate electrical connector of the MOSFET-switch to control the operation state of the MOSFET-switch. This allows to implement the above described functionality of the control unit in a functional and reliable manner.

Further, the voltage regulator is coupled to a current sense unit determining the electrical current flowing through the MOSFET-switch. The control unit is configured to use the determined information with regard to the electrical current flowing for controlling the MOSFET-switch. This configuration allows to set the specific amount of electrical current which is supplied to the second power port of the motor unit to the desired amount.

The MOSFET-switch comprises a n-channel MOSFET. Such n-channel MOSFET's are functional, effective and reliable implementations for MOSFET-switches.

A source electrical connector and a drain electrical connector of the MOSFET-switch are coupled to each other via a bridging diode. This bridging diode closes an electric circuit from the electric power supply via the motor unit to the ground in a functional and simple way, independently of the current operation state of the MOSFET-switch, such that the motor unit can be operated independently of the current operation mode of the MOSFET-switch.

The control circuit further comprises a first switching unit having at least one micro-switch. The first switching unit has a non-activated operation mode, in which electrical power can be supplied from the electric power supply to the first power port of the motor unit via a first power supply path in a first direction. The first switching unit has further an activated operation mode, in which electrical power cannot be supplied from the electric power supply to the motor unit via the first power port and in which the electrical power within the control circuit is introduced into the second power port of the motor unit in a second direction, being the reverse direction of the first direction. The first switching unit is configured to be switched from the non-activated operation mode to the activated operation mode when the drop bar reaches its upper end position or its lower end position. For the upper end position, this configuration prevents reliably that the drop bar collides with the base member damaging the window sun blind arrangement or damaging the motor unit by a therefrom resulting mechanical resistance. For the lower end position, this configuration prevents a further off-rolling of the dark-out-cloth fabric from the dark-out-cloth fabric roller and, thus, an undesired loss in tension for the extracted dark-out-cloth fabric.

Further, the at least one micro-switch comprises one input electrical connector and two output electrical connectors. The input electrical connector is coupled to the electric power supply. The first output electrical connector is coupled to the first power port of the motor unit. The second output electrical connector is coupled to the second power port of the motor unit. In the non-activated operation mode of the micro-switch, the input electrical connector is connected to the first output electrical connector. In the activated operation mode of the micro-switch (MS), the first output electrical connector is connected to the second output electrical connector. This configuration is simple and functional, resulting in a cheap and reliable overall configuration. Here, the first switching unit is activated by an off-rolling process of the window son blind arrangement.

Further, the first output electrical connector is coupled to the input electrical connector via a bridging diode, which is open in the direction from the first output electrical connector towards the input electrical connector. This bridging diode closes an electric circuit from the electric power supply via the motor unit to the ground in a functional and simple way and independently of the current operation state of the micro-switch. Hence, the motor unit can be operated independently of the current operation mode of the micro-switch.

Further, the first switching unit further comprises a bypass diode and a bypass resistor coupled to the second output electrical connector of the micro-switch in series with respect to each other. The bypass diode is open in the direction from the second output electrical connector towards the second power port of the motor unit. With the bypass resistor the electrical current introduced into the motor unit in the reverse direction can be set appropriately and the bypass diode prevents undesired electrical back couplings from the second power port to the micro-switch.

The control circuit further comprises at least one braking unit having a braking MOSFET-switch. The braking unit is configured to introduce an electrical power within the control circuit from the electric power supply into the motor unit after decoupling the control circuit in a reverse direction, as compared to its original operating direction, for braking the current movement of the motor unit. With this braking unit it is possible to brake the movement of the motor unit even for various operation states between the extended and the retracted operation state of the window sun blind arrangement. Thus, it is possible to stop the drop bar at any desired intermediate location between its upper end position and its lower end position in an effective and accurate way.

Further, the at least one braking unit is coupled to the first power supply path leading from the electric power supply to the first power port of the motor unit and to the second power supply path leading from the electric power supply to the second power port of the motor unit. The at least one braking unit is provided in such a manner that it is configured to brake an off-rolling process of the dark-out-cloth fabric from the dark-out-cloth fabric roller. Braking the motor unit just after an off-rolling process is especially advantageous as for the up-rolling process already the gravitational forces result in a braking of the movement, but for the off-rolling process the gravitational forces result in a further on-moving of the motor, which have to be braked.

Further, the at least one braking unit comprises a n-channel MOSFET-switch. Such n-channel MOSFET-switches are functional and reliable implementations for MOSFET-switches.

Further, a source electrical connector and a drain electrical connector of the braking MOSFET-switch are coupled to each other via a bridging diode. Such a bridging diode closes an electric circuit from the electric power supply via the motor unit to the ground independently of the current operation states of the braking unit in a functional, reliable and simple way.

Further, a gate electrical connector of the braking MOSFET-switch is connected to the first power supply path from the electric power supply to the first power port of the motor unit. A source electrical connector as well as a drain electrical connector of the braking MOSFET-switch are connected the second power supply path from the electric power supply to the second power port of the motor unit. With this configuration the above described functionality is achieved in a simple but reliable manner.

Further, the gate electrical connector is coupled to said first power supply path via an electrical resistor and a gate diode coupled in series to each other. With the resistor, the voltage level at the gate electrical connector of the braking MOSFET-switch can be set appropriately. The gate diode prevents undesired electrical back couplings from the gate electrical connector to the first power supply path.

Further, the gate electrical connector is further coupled to the second power supply path via an electrical resistor, a capacitor and/or a Zener diode. With these components the electrical properties and functions of the control circuit are improved.

According to a further aspect, a control circuit is provided for at least one of the above described window sun blind arrangements. A control circuit with such a configuration is able to achieve the above described technical effects for the window sun blind arrangement.

According to another aspect, a method for operating an electrically motorized window sun blind arrangement, in particular one of the above described window sun blind arrangements, comprises:
driving the electrically motorized window sun blind arrangement between a retracted and an extended operation state;
decoupling the motor unit from an electric power supply when the motor unit runs against a mechanical resistance, in particular when the electrically motorized window sun blind arrangement reaches its retracted state, and an electric current flowing through the motor unit exceeds a predetermined threshold value.

As already indicated above, with this method damages to the motor unit resulting from mechanical resistances can be prevented by shutting down the motor unit when such mechanical resistances occur.

According to a further aspect, a method for operating an electrically motorized window sun blind arrangement, in particular one of the above described window sun blind arrangements, comprises:
driving the electrically motorized window sun blind arrangement between a retracted and an extended operation state;
decoupling the motor unit from an electric power supply when the electrically motorized window sun blind arrangement reaches one of an upper end position or a lower end position; and
conducting a reverse current generated by the motor unit back into the motor unit in a reverse direction to brake the movement of the motor unit after decoupling the motor unit from the electric power supply
wherein a control circuit further comprises a first switching unit having a micro-switch (MS),
wherein the first switching unit has a non-activated operation mode, in which electrical power can be supplied from the electric power supply to a first power port of the motor unit via a first power supply path (I) in a first direction, and an activated operation mode, in which electrical power cannot be supplied from the electric power supply to the motor unit via the first power port and in which the electrical power within the control circuit is introduced into a second power port of the motor unit in a second direction, being the reverse direction of the first direction,
wherein the first switching unit is configured to be switched from the non-activated operation mode to the activated operation mode when a drop bar reaches its upper end position or its lower end position.

Thus, as already indicated above, damages to the window sun blind arrangement and/or an undesired loss of tension in the extracted dark-out-cloth fabric is prevented.

According to a last aspect, a method for operating an electrically motorized window sun blind arrangement, in particular one of the above described window sun blind arrangements, comprises:
driving the electrically motorized window sun blind arrangement between a retracted and anextended operation state;
decoupling a motor unit from an electric power supply at an intermediate operation state between the retracted and the extended operation state; and
conducting a reverse current generated by the motor unit back into the motor unit in a reverse direction to brake the movement of the motor unit after decoupling the motor unit from the electric power supply
wherein a control circuit further comprises at least one braking unit having a braking MOSFET-switch (M2),
wherein the at least one braking unit is configured to introduce an electrical power within the control circuit after decoupling the control circuit from an electric power supply into the motor unit in a reverse direction, as compared to its original operating direction, for braking its current movement.

As already indicated above, this method allows to stop the window sun blind accurately and precisely at any intermediate position.

### BRIEF DESCRIPTION OF THE DRAWINGS

These and other features of the invention will become more apparent from the following detailed description of non-limiting embodiments of the present embodiments, wherein reference is made to the accompanying drawings, in which:

FIG. 1 is a spatial view of a window sun blind arrangement according to one exemplary embodiment of the present invention; and

FIG. 2 is an exemplary wiring diagram for the driving means of the window sun blind arrangement of FIG. 1.

### DETAILED DESCRIPTION

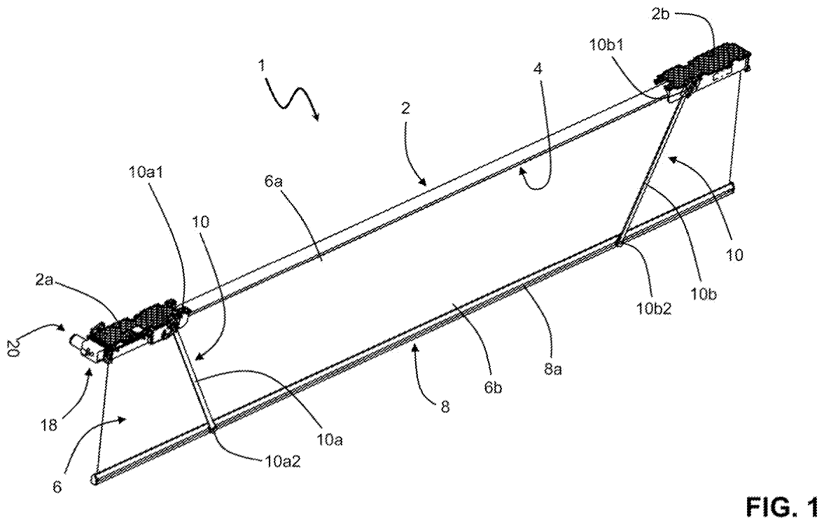

With reference to FIG. 1 a window sun blind arrangement 1 according to some embodiments is illustrated. The window sun blind arrangement 1 comprises a base member 2, a dark-out-cloth fabric roller 4, a dark-out-cloth fabric 6, a drop bar 8, a guiding means (arm) 10, a motor unit 18 and a control circuit 20. Such a window sun blind arrangement 1 in particular is configured to be used in vehicles like recreational vehicles as for example campers or caravans, or in commercial vehicles like for example lorries, busses or trains.

The base member 2 is configured to be mounted on a mounting surface like a wall of the vehicle. Therefore, the base member 2 can be provided with mounting holes for example provided in mounting sections 2a and 2b of the base member 2 and configured to be attached with mounting members (not illustrated) like for example screws to the wall. Of course, also other configurations for mounting the base member 2 to the wall are possible. The base member 2 can be provided as unitary one-piece member or can be divided in several sections which are coupled to each other. Here, the base member 2 comprises the above referenced mounting sections 2a and 2b and a coupling section 2c coupled to both of the mounting sections 2a and 2b.

The dark-out-cloth fabric roller 4 is provided in the form of an elongated tubular member coupled to the base member 2 in a rotatable manner, such that the dark-out-cloth fabric roller 4 can rotate with respect to the base member 2 about a longitudinal axis of the dark-out-cloth fabric roller 4. The longitudinal axis of the dark-out-cloth fabric roller 4 is parallel to a longitudinal axis of the base member 2.

The dark-out-cloth fabric 6 is formed of an in general rectangular panel of dark-out-cloth. Suitable materials and configurations for such dark-out-cloths are well known, which is why in the following further details with respect thereto are not described.

The dark-out-cloth fabric 6 has two longitudinal end portions 6a and 6b opposing each other. The first longitudinal end portion 6a of the dark-out-cloth fabric 6 is coupled to the dark-out-cloth fabric roller 4. Thus, the dark-out-cloth fabric 6 can be rolled off from the dark-out-cloth fabric roller 4 by rotating the dark-out-cloth fabric roller 4 with respect to the base member 2 in a first rotational direction. Further, the dark-out-cloth fabric 6 can be rolled up un onto the dark-out-cloth fabric roller 4 by rotating the dark-out-cloth fabric roller 4 in a second rotational direction which is inverse to the first rotational direction.

The drop bar 8 is provided as elongated rod member coupled to the second longitudinal end portion 6b of the dark-out-cloth fabric 6. The drop bar 8 is configured such that when the dark-out-cloth fabric 6 is rolled up onto the dark-out-cloth fabric roller 4 over its complete length, or at least near to its complete length, the drop bar 8 abuts against the base member 2. This prevents a further rotational movement of the dark-out-cloth fabric roller 4 with respect to the base member 2 in the second rotational direction. In this situation, the drop bar 8 is in its upper end position. Moreover, the drop bar 8 supports an off-rolling process of the dark-out-cloth fabric 6 from the dark-out-cloth fabric roller 4 and stretches the dark-out-cloth fabric 6 in any even partially rolled off configuration by gravitational forces applied onto the dark-out-cloth fabric 6.

The guiding means 10 is configured to guide the movement of the drop bar 8 along a predetermined path between its upper end position and a lower end position, in which the dark-out-cloth fabric 6 is substantially rolled off from the dark-out-cloth fabric roller 4. Here the guiding means 10 comprises two lever arms 10a and 10b. Each of the two lever arms 10a and 10b is coupled at a first longitudinal end portion thereof to the base member 2 in a pivotable manner and at a second longitudinal end portion thereof to the drop bar 8 in a slidable and rotatable manner. For example, the lever arms 10a and 10b can be coupled to the mounting sections 2a and 2b via common hinges 10a1 and 10b1 and to the drop bar 8 via sliding members 10a2 and 10b2 guided along a sliding rail 8a along the drop bar 8. Each of the sliding members 10a2 and 10b2 is coupled to the corresponding lever arm 10a or 10b via a further hinge (not illustrated). Thus, the lever arms 10a and 10b can support and guide the drop bar 8 in an appropriate manner. However, also other configurations are possible like, for example having guiding rails along which the drop bar 8 slides or configurations with hinged lever arms, in particular when there are strict space limitations.

The motor unit 18 and the control circuit 20 are parts of a driving means 12, which is configured to operate the window sun blind arrangement 1, i.e. to cause a movement of the various components of the window sun blind arrangement 1 with respect to each other. Although here, the window sun blind arrangement 1 is provided with only one motor unit 18 and only one control circuit 20, the window sun blind arrangement 1 can be provided with more than one motor unit 18 and/or control circuit 20, like for example two.

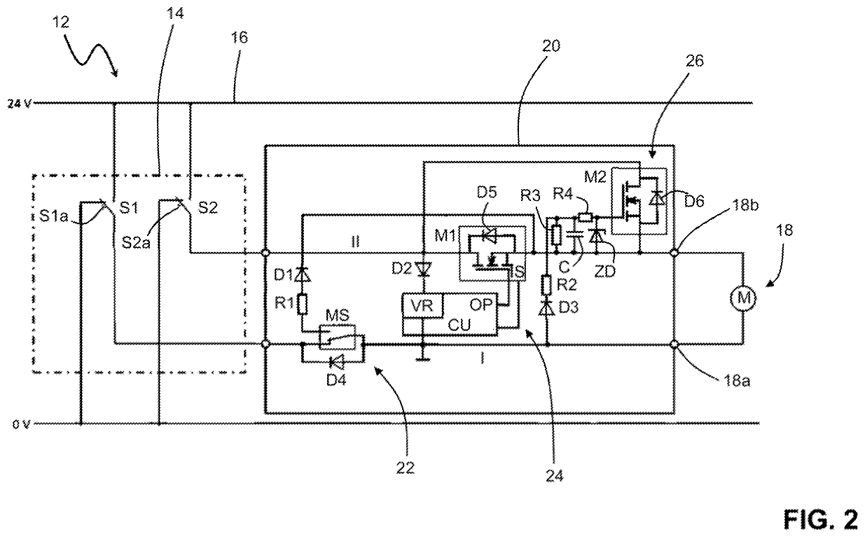

A detailed description of the principle structural configuration and function of the driving means 12, and thus of the motor unit 18 and of the control circuit 20 is provided in the following with respect to FIG. 2.

The driving means 12 comprises an operating unit 14, an electric power supply 16, the motor unit 18 and the control circuit 20. Here, the operating unit 14 and the electric power supply 16 are not elements of the sun blind arrangement 1 but merely coupled thereto. However, also configurations in which these components are also elements of the window sun blind arrangement 1 are possible.

The electric power supply 16 is coupled with the motor unit 18 via the operating unit 14 and the control circuit 20. In the illustrated example, the electric power supply 16 is the on-board power system of the vehicle. However also other implementations are possible.

The motor unit 18 comprises an electrical motor M. The electrical motor M can be driven in two opposing directions depending on the direction in which electrical power is guided through the motor M. Therefore, the motor unit 18 comprises two power ports 18a and 18b by which the motor M is connected to the control circuit 20. The motor M of the motor unit 18 is coupled to the base member 2 and the dark-out-cloth fabric roller 4 in such a manner that the motor M is able to rotate the dark-out-cloth fabric roller 4 either in an off-rolling direction corresponding the first rotational direction or in an up-rolling direction corresponding the second rotational direction, depending on the direction of the current guided through the motor M.

The electric power supply 16 is configured to provide enough electrical energy to drive the motor M. For example, the electric power supply 16 can comprise a 24 Volt power supply. However, also other voltage levels are possible.

The operating unit 14 and the control circuit 20 form two parallel power supply paths I and II. The first power supply path I is leading from the electric power supply 16 to the first power port 18a of the motor unit 18. The second power supply path II is leading from the electric power supply 16 to the second power port 18b of the motor unit 18. The first power supply path I is provided to supply the motor M with electrical power to move the dark-out-cloth fabric roller 4 in the first rotational direction, i.e. the off-rolling direction. The second power supply path II is provided to supply the motor M with electrical power to move the dark-out-cloth fabric roller 4 in the second rotational direction, i.e. the up-rolling direction.

The operating unit 14 comprises two operating switches S1 and S2, one for each power supply path I and II. Each of the switches S1 and S2 is configured to have two operation states and the switches S1 and S2 are operable independently of each other. In a first operation state, the corresponding switch S1 or S2 is in a non-operated position in which corresponding power supply path I or II is cut and the respective power port 18a or 18b of the motor unit 18 is connected with ground. In a second operation state, the corresponding switch S1 or S2 is in an operated position in which the switch S1 or S2 closes the respective power supply path I or II, i.e. connects the power supply 16 with the corresponding power port 18a or 18b of the motor unit 18. In FIG. 2, both switches S1 and S2 are in the non-operated position. Each of the switches S1 and S2 comprise a biasing member S1a or S2a biasing the corresponding switch S1 or S2 into the non-operated position when the respective switch S1 or S2 is not operated. Here, the two switches S1 and S2 are provided as manually operated toggle switches. However, also configurations with electrically operable switches, which for example can be operated via remote control or similar implementations can be provided.

As can be taken further from FIG. 2, the control circuit 20 comprises a first switching unit 22 in the first power supply path I leading from electric power supply 16 to the first power port 18a of the motor unit 18.

The first switching unit 22 comprises a micro-switch MS having an input electrical connector coupled to the electric power supply 16, i.e. connected to the first switch S1 side of the first power supply path I, a first output electrical connector coupled to the first power port 18a of the motor unit 18, i.e. connected to the motor unit 18 side of the first power supply path I, and a second output electrical connector coupled to the second power port 18b of the motor unit 18.

The micro-switch MS has two different operation modes. In a non-activated operation mode, the input electrical connector of the micro-switch MS is connected with the first output electrical connector of the micro-switch MS. Thus, electrical power can be transferred from the electric power supply 16 to the first power port 18a of the motor unit 18 to rotate the dark-out-cloth fabric roller 4 in the first rotational direction, depending on the operation state of the first switch S1. As soon the drop bar 8 reaches the corresponding end position, which is here the lower end position, while the first switch S1 is operated, the operation mode of the micro-switch MS changes to an activated operation mode of the micro-switch MS, in which the first output electrical connector of the micro-switch MS is connected to the second output electrical connector of the micro-switch MS. Thus, the two power ports 18a and 18b of the motor unit are short-circuited and electrical power from the motor unit 18 side of the first power path I is guided to the second power port 18b of the motor unit 18. Thus, the electrical power is introduced into the motor unit 18 in the reverse direction, resulting in a braking of the movement of the motor M. Therewith, as soon as the micro-switch MS is switched from the non-activated operation mode to the activated operation mode, the reverse current generated by the motor unit 18 flows through a bypass resistor R1 and a bypass diode D1 to the motor unit 18 to brake the movement of the motor M. Thus, the motor M is stopped much faster.

Here, the micro-switch MS is configured in such a way that it is switched from the non-activated operation mode to the activated operation mode in a situation in which the drop bar 8 reaches its lower end position. Therefore, the micro-switch MS, for example, can be provided as stop switch which is activated when the drop bar 8 abuts against a corresponding element of the micro-switch MS. Alternatively, the micro-switch MS can be provided as stop switch which is activated by the guiding means 10, when the guiding means 10 reaches a position in which the drop bar 8 is expected to be in its respective end position.

Here, the first power supply path I is coupled to the motor unit 18 in such a manner that an electrical current from the electric power supply 16 via the first power supply path I to the motor unit 18 and back through the second power supply path II to the ground results in the motor M rotating the dark-out-cloth fabric roller 4 in the first rotational direction, i.e. in the off-rolling direction. Accordingly, the micro-switch MS is to be configured such that it is activated when the drop bar 8 is in its lower end position. However, also other configurations are possible.

In other words, the micro-switch MS is in the non-activated operation mode as long as the drop bar 8 is not in its lower end position. When the first switch S1 is operated, the motor unit 18 is supplied with electrical power from the electric power supply 16 such that the motor M rotates the dark-out-cloth fabric roller 4 in the off-rolling direction. This results in the dark-out-cloth fabric 6 rolling off from the dark-out-cloth fabric roller 4 and the drop bar 8 moving towards its lower end position (by gravitational forces). As soon as the drop bar 8 reaches its lower end position, the first switching unit 22, i.e. micro-switch MS, is activated to cut the electrical connection between the electric power supply 16 and the motor unit 18 and to direct the electrical power respectively the current generated by the motor M through the motor unit 18 side of the first power path I, the micro-switch MS, the bypass resistor R1 and the bypass diode D1 back to the motor unit 18 in the reverse direction.

This results in a sudden braking of the movement of the motor M and thus in a fast standstill or stop of the motor M such that no more dark-out-cloth fabric 6 is rolled off from the dark-out-cloth fabric roller 4, even if there would be still some dark-out-cloth fabric 6 rolled onto the dark-out-cloth fabric roller 4.

Thus, the dark-out-cloth fabric 6 does not loose its tension generated by the gravitational forces from the drop bar 8, when the drop bar 8 reaches its lower end position.

When use in the up-rolling direction, such a switching unit can prevent that the drop bar 8 runs against the base member 2 and blockades the not yet stopped motor M. Therewith, damages to the motor M are prevented in a reliable and efficient way.

The first switching unit 22 further comprises a bridging diode D4. The bridging diode D4 connects the first output electrical connector with the input electrical connector in a reverse direction, i.e. in a direction from the motor unit 18 side of the first power supply path I towards the electric power supply 16 side of the first power supply path I. The bridging diode D4 serves to close an electrical path from the power supply via the second switch S2 (in the operated position) to the motor unit 18 and back via the first switch S1 (in the non-operated position) to ground, independently of the operation mode of the micro-switch MS.

As indicated above, the switching unit 22 comprises the bypass diode D1 and the bypass resistor R1 provided in the electrical connection between the second output electrical connector of the micro-switch MS and the second power port 18b of the motor unit 18. With the bypass resistor R1, the specific current generated by the motor unit 18 in the reverse direction is set and the bypass diode D1 prevents that electrical current is introduced into the micro-switch MS from the second power supply path II.

Moreover, the control circuit 20 comprises in the second power supply path II leading from the electric power supply 16 to the second power port 18b of the motor unit 18 a second switching unit 24.

The second switching unit 24 comprises a MOSFET-switch M1 having a drain electrical connector coupled to the electric power supply 16, i.e. connected to the second switch S2 side of the second power supply path II, a source electrical connector coupled to the second power port 18b of the motor unit 18, i.e. connected to the motor unit 18 side of the second power supply path II, and a gate electrical connector M1 connected to an output port OP of a control unit CU. Thus, the control unit CU for the MOSFET-switch M1 controls the operation state of the MOSFET-switch, i.e. whether the MOSFET-switch M1 connects the electric power supply 16 with the second power port 18b of motor unit 18 or not.

The MOSFET-switch M1 has two different operation states, namely an activated operation state and a non-activated operation state. In the activated operation state, the source electrical connector of the MOSFET-switch M1 is connected via a space-charge region generated by the control unit CU in the MOSFET-switch M1, with the drain electrical connector. Thus, electrical power can be transferred from the electric power supply 16 to the second power port 18b of the motor unit 18, when the second switch S2 is in the operated position. In the non-activated operation state of the MOSFET-switch M1, there is no space-charge region formed within the MOSFET-switch M1 such that no electrical current can flow from the electric power supply 16 through the MOSFET-switch M1 to the second power port 18b of the motor unit 18.

The control unit CU is configured in such a way that it switches the MOSFET-switch M1 only from the activated operation state to the non-activated operation state when the motor M of the motor unit 18 runs against a mechanical resistance. Therefore, the control unit CU comprises a voltage regulator VR measuring the voltage level applied to the motor unit 18. The voltage regulator VR is coupled to the second power supply path II on the electric power supply 16 side with respect to the MOSFET-switch M1 and to the first power supply path I on the motor unit 18 side with respect to the first switching unit 22. Thus, the control unit CU is configured to determine the voltage level applied to the motor unit 18 and, thus, to control the MOSFET-switch M1 in an appropriate manner based on the determined voltage level. In particular, the control unit CU switches the operation state of the MOSFET-switch M1 from the activated operation state to the non-activated operation state by cancelling the application of an appropriate voltage on to the gate electrical connector for forming the space-charge region within the MOSFET-switch M1, when the current flowing through the MOSFET-switch M1 and the motor unit 18 measured by an internal circuit exceeds a predetermined threshold value. The motor-current measured by the internal circuit is provided by means of a proportional voltage through MOSFET-switch M1 output “IS” to the control unit CU.

Thus, when the motor M of the motor unit 18 runs against a mechanical resistance of a predetermined amount, the second power supply path II is cut and thus the motor M of the motor unit 18 is not supplied with electrical power from the electric power supply 16 via the second power port 18b, independently of the current operation position of the second switch S2. Therewith, it is possible to prevent a stuck of the motor M or damages to the motor M. This, in particular, is of specific importance if the motor unit 18 comprises a worm gear motor as such motors are highly sensitive to such problems.

As may be taken further from FIG. 2, the control unit CU of the second switching unit 24 is coupled to the second power supply path II via a regulator diode D2. This prevents an electrical current flowing through the control unit CU into the second power supply path II in a supply-voltage-reverse—polarity condition, which could damage the control unit CU. Furthermore, the control unit CU is coupled to a current sense unit IS. The current sense unit IS is configured to measure the current value within the MOSFET-switch M1 and to provide the control unit CU with a corresponding signal. The control unit CU receives this signal and uses this signal to control the voltage level at the output port OP such that the MOSFET-switch M1 is operated in the activated or in the non-activated operation state, and the electrical current flows through the MOSFET-switch M1 in the activated operation state.

Similar to the micro-switch MS, also the MOSFET-switch M1 comprises a bridging diode D5, to close the electric circuit from the electric power supply 16 through the activated first switch S1 to the motor unit 18 and back through the non-activated second switch S2 to the ground. Here, the bridging diode D5 is an intrinsic element of the MOSFET-switch M1.

Here, the MOSFET-switch M1 is provided as n-channel MOSFET. In such a n-channel MOSFET, the source electrical contact is further connected to the bulk of the MOSFET-switch M1. This allows to prevent negative influences of an occurring voltage between the source electrode connector and the bulk of the MOSFET-switch M1.

The second switching unit 24 is provided within the second power supply path II, which is provided to operate the motor M of the motor unit 18 in the up-rolling direction. Thus, the MOSFET-switch M1 is switched from the activated operation state to the non-activated operation state just when the motor unit 18 runs against a mechanical resistance during an up-rolling process of the dark-out-cloth fabric 6 onto the dark-out-cloth fabric roller 4. In particular, the MOSFET-switch M1 is switched from the activated operation state, in which the motor unit 18 can be supplied with electrical power from the electric power supply 16 to roll up the dark-out-cloth fabric 6 onto the dark-out-cloth fabric roller 4, to the non-activated operation state, in which the motor cannot be supplied with electrical power from the electric power supply 16 in the up-rolling direction, when the drop bar 8 reaches its upper end position.

In other words, in its upper end position, the drop bar 8 abuts against the base member 2. Thus, the drop bar 8 hinders the further up-rolling of the dark-out-cloth fabric 6 onto the dark-out-cloth fabric roller 4 and, therewith, the further rotation of the dark-out-cloth fabric roller 4 in the second direction. This results in a mechanical resistance for the motor M of the motor unit 18. Alternatively, also other external influences like a use holding the drop bar 8 can result in such a mechanical resistance. As soon as this mechanical resistance reaches a predetermined value, corresponding to a correspondingly determined threshold value of the current flowing through the motor unit 18, the MOSFET-switch M1 is switched from the activated operation state to the non-activated operation state to cut the second power supply path II. Thus, the motor M is stopped and damages to the motor M of the motor unit 18 resulting from such mechanical resistances can be prevented in a functional and reliable way.

It is unnecessary to point out that the predetermined threshold value has to be selected high enough such that the motor M still can be operated to roll up the dark-out-cloth fabric 6 onto the dark-out-cloth fabric roller 4 against the gravitational force of the off-rolled portion of the dark-out-cloth fabric 6 and of the drop bar 8 as well against customary internal frictional forces within the window sun blind arrangement 1, like frictional forces between the dark-out-cloth fabric roller 4 and the base member 2 and/or from the guiding means 10. However, the predetermined threshold value has to be selected low enough to prevent substantial damages to or malfunctions of the motor M resulting from the mechanical resistances. If there is no appropriate threshold value to be determined, the motor M as to be replaced by another one with corresponding characteristics or the other components of the window sun blind arrangement 1 have to be modified accordingly.

Finally, the control circuit 20 further comprises a braking unit 26 coupled to the two power supply paths I and II.

The braking unit 26 comprises a braking MOSFET-switch M2 having a drain electrical connector coupled to the electric power supply 16, i.e. connected to the second switch S2 side of the second power supply path II with respect to the second switching unit 24, a source electrical connector coupled to the second power port 18b of the motor unit 18, i.e. connected to the motor unit 18 side of the second power supply path II with respect to the second switching unit 24, and a gate electrical connector coupled to the first power port 18a of the motor unit 18, i.e. connected to the motor unit 18 side of the first power supply path I with respect to the first switching unit 22.

The braking MOSFET-switch M2 has two different operation states. In a non-activated operation state, the source electrical connector of the braking MOSFET-switch M2 is not connected via a space-charge region generated by an electrical voltage applied to the gate electrical connector of the braking MOSFET-switch M2 to the drain electrical connector thereof. In an activated operation state of the braking MOSFET-switch M2, the voltage level applied to the gate electrical connector generates a space-charge region to connect the source electrical connector to the drain electrical connector. Thus, when an off-rolling process of the dark-out-cloth fabric 6 from the dark-out-cloth fabric roller 4 is canceled by releasing the first switch S1, the MOSFET-switch M2 is switched to the activated operation state. In this operation state, electrical power of the motor unit 18 respectively the generated reverse current generated by the motor M can be transferred through the first power port 18a, through the micro-switch MS and then through the first switch S1 through ground and then through the second switch S2 (which is also connected to ground) back to the second power supply path II and finally to the second power port 18b of the motor unit 18 and, thus, into the motor unit 18 in the reverse direction. This results in a braking of the movement of the motor M of the motor unit 18. Thus, the off-rolling process is stopped much faster. This prevents an undesired run-on of the motor M and, thus, a further off-rolling of the dark-out-cloth fabric 6 from the dark-out-cloth fabric roller 4 if the drop bar 8 is at an intermediate position between its upper end position and its lower end position.

The braking unit 26 is coupled to the two power supply paths I and II in the way described above such that the braking unit 26 is configured to brake the further movement of the motor M just during off-rolling processes. As for up-rolling processes the gravitational forces acting on the drop bar 8 already result in an appropriate braking of the motor M. However, a braking unit very similar to the braking unit 26 can also be provided in such a manner that it brakes the motor M after cancelling an up-rolling process. Therefore, the braking unit 26 just would have to be coupled to the two power supply paths I and II in an inverse manner. In such a configuration, the drain electrical connector of the braking MOSFET-switch M2 would be connected to the first switch S1 side of the first power supply path I with respect to the first switching unit 22, the source electrical connector would be connected to the motor unit 18 side of the first power supply path I with respect to the first switching unit 24, and the gate electrical connector would be connected to the motor unit 18 side of the second power supply path II with respect to the second switching unit 24.

Similar to the MOSFET-switch M1 also the braking MOSFET-switch M2 comprises an internal bridging diode D6. The bridging diode D6 closes an electric circle from the electric power supply 16 through the activated first switch S1 to the motor unit 18 and back through the non-activated second switch S2 to the ground.

Furthermore, in this configuration the braking MOSFET-switch M2 is also provided as n-channel MOSFET.

As is illustrated in FIG. 2, the gate electrical connector of the braking MOSFET-switch M2 is coupled to the motor unit 18 side of the first power supply path I via an electrical resistor R2 and a gate diode D3. Thus, the voltage level applied to the gate electrical connector can be set appropriately and no electrical current is introduced from the gate electrical connector of the braking MOSFET-switch M2 to the first power supply path I. Moreover, the gate electrical connector of the braking MOSFET-switch M2 is coupled to the second power supply path II on the motor unit 18 side with respect to the second switching unit 24 via an electrical resistor R3, a capacitor C and a Zener diode ZD. Furthermore, a further electrical resistor R4 is provided between each of the electrical resistors R2 and R3, the gate diode D3 and the capacitor C, and the gate electrical connector of the braking MOSFET-switch M2. These structural features improve the electrical characteristics and functionality of the braking unit 26 substantially. As the effects of these structural elements are clear to a skilled artisan, a detailed description thereof is omitted for the sake of brevity.

Although not illustrated here explicitly, the present invention also refers to the above described control circuit 20 for such a window sun blind arrangement 1 and a vehicle comprising such a window sun blind arrangement 1. For example, the front window or side window of the vehicle can be equipped with a window sun blind arrangement 1 according to the present invention.

In the following, various methods for operating a window sun blind arrangement, in particular for operating the above described window sun blind arrangement 1, will be described in detail.

In all methods described, the sun blind arrangement 1 is driven between its retracted and its extended operation state in principle corresponding the operation states in which the drop bar 8 is in its upper end position or in its lower end position.

According to a first method, when the window sun blind arrangement 1 reaches one of its end position, i.e. is in either the retracted or extended operation state, the motor unit 18 is decoupled from the electric power supply 16. This, in particular, is done by the control circuit 20. Then, the electrical power within the control circuit 20 respectively the reverse current generated by the motor unit 18 of the window sun blind arrangement 1 is conducted by a first switching unit 22 back into the motor unit 18 in a reverse direction in order to brake the movement of the motor unit 18. In particular, the first switching unit 22 is switched from the non-activated operation mode to the activated operation mode to achieve this effect. Thus, the motor unit 18 is braked when the drop bar 8 reaches one of its end positions, in particular when the drop bar 8 is reaching its lower end position. This prevents efficiently a loosening of the tension for the dark-out-cloth fabric 6 and damages to the motor unit 18 caused by a mechanical resistance.

According to a second method, when the window sun blind arrangement 1 reaches its retracted operation state, i.e. the drop bar 8 is in its upper end position resulting in an increased mechanical resistance for the motor unit 18, the motor unit 18 is decoupled from the electric power supply 16. This is done by the control circuit 20. This decoupling is triggered as soon as a predetermined threshold value of the current flowing through the motor unit 18 is reached, which is corresponding to a predetermined mechanical resistance. In particular, the second switching unit 24 is switched from the activated operation state to the non-activated operation state thereof to achieve the decoupling (i.e. to switch off the motor M). Thus, the motor unit 18 is saved against damages from increasing mechanical resistances for the motor unit 18.

According to a third method, when the motor unit 18 is decoupled from the electric power supply 16 at an intermediate operation state of the window sun blind arrangement 1 between the retracted and the extended operation state, the electrical power within the control circuit 20 respectively the reverse current generated by the motor unit 18 of the window sun blind arrangement 1 is conducted by a braking unit within the control circuit back to the motor unit 18 in order to brake the movement of the motor unit 18, which in particular is done by the control circuit 20. Therewith the movement of the motor unit 18 is braked efficiently. In particular, the braking unit 26 is operated to achieve this effect. Thus, the motor unit 18 is braked when the window sun blind arrangement 1 is to be stopped at an intermediate operation state thereof preventing or at least reducing a running on of the motor unit 18 and, thus, a further rolling-off or rolling-up of the dark-out-cloth-fabric 6 from/onto the dark-out-cloth fabric roller 4.

Of course, all these methods can be combined to one single method with several different reactions on various situations. In particular, when the drop bar 8 reaches its lower end position, the first method is carried out. When the drop bar 8 reaches its upper end position, the second method is carried out. And, finally, when the drop bar 8 is stopped at an intermediate position, the third operation mode is carried out.

It is to be noted that the scope of protection of this application is defined by the appending claims and not by the above description of an exemplary embodiment for the present invention. In particular, it is pointed to the fact that the various components like the two switching units 22 and 24 and/or the braking unit 26 can be combined in various manners resulting in a useful and advantageous overall configuration for the control circuit 20.

### REFERENCE NUMERALS

1 window sun blind arrangement
2 base member
2a first mounting section
2b second mounting section
2c coupling section
4 dark-out-cloth fabric roller
6 dark-out-cloth fabric
6a first longitudinal end portion
6b second longitudinal end portion
8 drop bar
8a sliding rail
10 guiding means (arm)
10a first lever arm
10a1 first hinge
10a2 first sliding member
10b second lever arm
10b1 second hinge
10b2 second sliding member
12 driving means
14 operating unit
16 electric power supply
18 motor unit
20 control circuit
22 first switching unit
24 second switching unit
26 braking unit
CU control unit
D1 bypass diode
D2 regulator diode
D3 gate diode
D4 bridging diode
D5 bridging diode
D6 bridging diode
IS current sense unit
M motor
M1 MOSFET-switch
M2 braking MOSFET-switch
MS micro-switch
OP output port
R1 bypass resistor
R2 electrical resistor
R3 electrical resistor
R4 electrical resistor
first switch
S1a first biasing member
S2 second switch
S2a second biasing member
VR voltage regulator
ZD Zener diode
I first power supply path
II second power supply path

1. A window sun blind arrangement for a vehicle, comprising:
a base member, wherein the base member is configured to be attached to a supporting surface;
a dark-out-cloth fabric roller, wherein the dark-out-cloth fabric roller is attached in a rotatable manner to the base member;
a dark-out-cloth fabric, wherein the dark-out-cloth fabric has a first and a second longitudinal end portion, wherein the first longitudinal end portion of the dark-out-cloth fabric is coupled to the dark-out-cloth fabric roller so that the dark-out-cloth fabric can be rolled up onto or rolled off from the dark-out-cloth fabric roller by rotating the dark-out-cloth fabric roller with respect to the base member;
a drop bar, wherein the second longitudinal end portion of the dark-out-cloth fabric is coupled to the drop bar;
a guiding arm, wherein the guiding arm is coupled to the base member and the drop bar and is configured to guide the movement of the drop bar with respect to the base member along a predetermined path between an upper end position, in which the dark-out-cloth fabric is fully rolled up onto the dark-out-cloth fabric roller, and a lower end position, in which the dark-out-cloth fabric is fully rolled off from the dark-out-cloth fabric roller;
an electrical motor unit, wherein the motor unit comprises two power ports and is configured to control the rotational movement of the dark-out-cloth fabric roller with respect to the base member based on a voltage level applied via the two power ports to the motor unit; and
a control circuit, wherein the control circuit is configured to be coupled via an operating unit to an electric power supply, is coupled to the motor unit, and is configured to operate the motor unit with electrical power from the electric power supply depending on an operation state of the operating unit;
wherein
the control circuit comprises a second switching unit having a MOSFET-switch (M1),
wherein the second switching unit comprises a control unit (CU) configured to operate the MOSFET-switch (M1),
wherein the MOSFET-switch (M1) has an activated operation state, in which electrical power can be supplied from the electric power supply to the second power port of the motor unit via a second power supply path (II), and a non-activated operation state, in which electrical power cannot be supplied from the electric power supply to the motor unit via the second power supply path (II),
wherein the control unit (CU) is configured to operate the MOSFET-switch (M1) in the activated operation state, when an electric current flowing through the MOSFET-switch (M1) and the motor unit does not exceed a predetermined threshold value, and to operate the MOSFET-switch (M2) in the non-activated operation state, when current flowing through the MOSFET-switch (M1) and the motor unit exceeds the predetermined threshold value.

2. The window sun blind arrangement of claim 1, wherein the second power supply path (II) leading from the electric power supply to the motor unit is configured to provide the motor unit with electrical power for an up-rolling process of the dark-out-cloth fabric onto the dark-out-cloth fabric roller.

3. The window sun blind arrangement of claim 2, wherein the second switching unit is configured to stop the up-rolling process of the dark-out-cloth fabric onto the dark-out-cloth fabric roller as soon as the drop bar and thus the motor unit runs against a mechanical resistance.

4. The window sun blind arrangement of claim 1, wherein the motor unit comprises a worm gear motor.

5. The window sun blind arrangement of claim 1, wherein
a threshold value for the electric current flowing through the MOSFET-switch (M1) and the motor unit is selected in such a manner that the MOSFET-switch (M2) is activated before the motor unit gets stuck or takes damages from a mechanical resistance.

6. The window sun blind arrangement of claim 1, wherein
the control unit (CU) comprises a voltage regulator (VR), which is coupled to a first power supply path (I) leading from the electric power supply to the first power port of the motor unit, via a regulator diode (D2).

7. The window sun blind arrangement of claim 6, wherein
the voltage regulator (VR) is coupled to a gate electrical connector of the MOSFET-switch (M2) to control the operation state of the MOSFET-switch (M2).

8. The window sun blind arrangement of claim 6, wherein
the voltage regulator (VR) is coupled to a current sense unit (IS) determining the electrical current flowing through the MOSFET-switch (M2),
wherein the control unit (CU) is configured to use the determined information with regard to the electrical current flowing for controlling the MOSFET-switch (M2).

9. The window sun blind arrangement of claim 1, wherein
the MOSFET-switch (M2) comprises a n-channel MOSFET.

10. The window sun blind arrangement of claim 1, wherein
a source electrical connector and a drain electrical connector of the MOSFET-switch (M2) are coupled to each other via a bridging diode (D5).

11. The window sun blind arrangement of claim 1, wherein
the control circuit further comprises a first switching unit having at least one micro-switch (MS),
wherein the first switching unit has a non-activated operation mode, in which electrical power can be supplied from the electric power supply to the first power port of the motor unit via a first power supply path (I) in a first direction, and an activated operation mode, in which electrical power cannot be supplied from the electric power supply to the motor unit via the first power port and in which the electrical power within the control circuit is introduced into the second power port of the motor unit in a second direction, being the reverse direction of the first direction,
wherein the first switching unit is configured to be switched from the non-activated operation mode to the activated operation mode when the drop bar reaches its upper end position or its lower end position.

12. The window sun blind arrangement of claim 11, wherein
the at least one micro-switch (MS) comprises one input electrical connector and two output electrical connectors, wherein the input electrical connector is coupled to the electric power supply, the first output electrical connector is coupled to the first power port of the motor unit and the second output electrical connector is coupled to the second power port of the motor unit,
wherein in the non-activated operation mode of the micro-switch (MS), the input electrical connector is connected to the first output electrical connector, and in the activated operation mode of the micro-switch (MS), the first output electrical connector is connected to the second output electrical connector.

13. The window sun blind arrangement of claim 12, wherein
the first output electrical connector is coupled to the input electrical connector via a bridging diode (D4), which is open in the direction from the first output electrical connector towards the input electrical connector.

14. The window sun blind arrangement of claim 12, wherein
the first switching unit further comprises a bypass diode (D1) and a bypass resistor (R1) coupled to the second output electrical connector of the micro-switch (MS) in series with respect to each other,
wherein the bypass diode (D1) is open in the direction from the second output electrical connector towards the second power port of the motor unit.

15. The window sun blind arrangement of claim 1, wherein
the control circuit further comprises at least one braking unit having a braking MOSFET-switch (M2),
wherein the at least one braking unit is configured to introduce an electrical power within the control circuit after decoupling the control circuit from the electric power supply into the motor unit in a reverse direction, as compared to its original operating direction, for braking its current movement.

16. The window sun blind arrangement of claim 15, wherein
the at least one braking unit is coupled to the first power supply path (I) leading from the electric power supply to the first power port of the motor unit and to the second power supply path (II) leading from the electric power supply to the second power port of the motor unit, and
wherein the at least one braking unit is provided in such a manner that it is configured to brake an off-rolling process of the dark-out-cloth fabric from the dark-out-cloth fabric roller.

17. The window sun blind arrangement of claim 15, wherein the at least one braking unit comprises a n-channel MOSFET.

18. The window sun blind arrangement of claim 15, wherein a source electrical connector and a drain electrical connector of the braking MOSFET-switch (M2) are coupled to each other via a bridging diode (D6).

19. The window sun blind arrangement of claim 15, wherein a gate electrical connector of the braking MOSFET-switch (M2) is connected to the first power supply path (I) from the electric power supply to the first power port of the motor unit and a source electrical connector as well as a drain electrical connector of the braking MOSFET-switch (M2) are connected to the second power supply path (II) from the electric power supply to the second power port of the motor unit.

20. The window sun blind arrangement of claim 19, wherein the gate electrical connector is coupled to said first power supply path (I) via an electrical resistor (R2) and a gate diode (D3) coupled in series to each other.

21. The window sun blind arrangement of claim 19, wherein the gate electrical connector is further coupled to the second power supply path (II) via an electrical resistor (R3), a capacitor (C) and/or a Zener diode (ZD).

22. A method for operating an electrically motorized window sun blind arrangement, comprising:
driving the electrically motorized window sun blind arrangement between a retracted and an extended operation state;
decoupling the motor unit from an electric power supply when the motor unit runs against a mechanical resistance, in particular when the window sun blind arrangement reaches its retracted state, and an electric current flowing through the motor unit exceeds a predetermined threshold value.

23. A method for operating an electrically motorized window sun blind arrangement, comprising:
driving the electrically motorized window sun blind arrangement between a retracted and an extended operation state;
decoupling the motor unit from an electric power supply when the electrically motorized window sun blind arrangement reaches one of an upper end position or a lower end position;
conducting a reverse current generated by the motor unit back into the motor unit in a reverse direction to brake the movement of the motor unit after decoupling the motor unit from the electric power supply;
wherein a control circuit further comprises a first switching unit having a micro-switch (MS),
wherein the first switching unit has a non-activated operation mode, in which electrical power can be supplied from the electric power supply to a first power port of the motor unit via a first power supply path (I) in a first direction, and an activated operation mode, in which electrical power cannot be supplied from the electric power supply to the motor unit via the first power port and in which the electrical power within the control circuit is introduced into a second power port of the motor unit in a second direction, being the reverse direction of the first direction; and,
wherein the first switching unit is configured to be switched from the non-activated operation mode to the activated operation mode when a drop bar reaches its upper end position or its lower end position.

24. A method for operating an electrically motorized window sun blind arrangement, comprising:
driving the electrically motorized window sun blind arrangement between a retracted and an extended operation state;
decoupling a motor unit from an electric power supply at an intermediate operation state between the retracted and the extended operation state; and
conducting a reverse current generated by the motor unit back into the motor unit in a reverse direction to brake the movement of the motor unit after decoupling the motor unit from the electric power supply;
wherein a control circuit further comprises at least one braking unit having a braking MOSFET-switch (M2); and,
wherein the at least one braking unit is configured to introduce an electrical power within the control circuit after decoupling the control circuit from an electric power supply into the motor unit in a reverse direction, as compared to its original operating direction, for braking its current movement.
